(19) United States
(12) Patent Application Publication
(10) Pub. No.: US 2007/0134598 A1
(43) Pub. Date: Jun. 14, 2007

(54) Manufacturing method of semiconductor device, and wafer and manufacturing method thereof

(75) Inventor: Shigeru Iwamoto, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/405,634

(22) Filed: Apr. 18, 2006

(30) Foreign Application Priority Data
Dec. 9, 2005 (JP) 2005-355625

(51) Int. Cl. G03F 7/20

(52) U.S. Cl. 430/311; 430/394

(57) ABSTRACT

A semiconductor device manufacturing method which makes it possible to accurately grasp chip positions on a wafer. The method comprises the steps of forming an uppermost layer wiring, a passivation film and a resist; exposing, using a reticle having formed thereon a pad pattern, exposure shot regions excluding one exposure shot region out of all exposure shot regions of the resist; exposing, using a reticle having formed thereon a pattern different from the pad pattern, the one remaining exposure shot region; developing the whole resist to form resist patterns; and etching the passivation film using the resist pattern as masks to respectively form a pad for a product chip and an opening section of a reference chip in the regions exposed using these different reticles. Thus, the product chip and the reference chip can be discriminated by image recognition so that chip positions on the wafer can be accurately grasped.

### CROSS-REFERENCE TO RELATED APPLICATIONS

This application is based on, and claims priority to, Japanese Application No. 2005-355625, filed Dec. 9, 2005, in Japan, and which is incorporated herein by reference.

### BACKGROUND OF THE INVENTION

1. Field of the Invention

The present invention relates to a manufacturing method of a semiconductor device, and a wafer and a manufacturing method of the wafer. More particularly, the present invention relates to a semiconductor device manufacturing method having an exposure step using a reticle. The invention also pertains to a wafer having formed thereon plural chips and a manufacturing method of the wafer.

2. Description of the Related Art

Conventionally, in a manufacture of semiconductor devices, plural inspections are usually performed on semiconductor devices kept in a wafer state until the semiconductor devices are completed. The inspection ranges widely in type. Examples of the inspection include a probe inspection and a visual inspection. The prove inspection is an inspection in which an inspection probe is sequentially brought into contact with each chip formed in a wafer to perform measurement of a predetermined characteristic value. The visual inspection is an inspection using a microscope. In the probe inspection or visual inspection, a quality judgment of each chip is performed based on inspection results thereof and at the same time, marking on chips judged to be defective is normally performed in order to facilitate subsequent discrimination of chips. Further, after passing -through various inspection steps, dicing is performed. Then, only non-defective chips with no marking are picked up and conveyed to a subsequent assembling step.

When screening non-defective chips during the marking or the picking up, for example, a reference chip is specified by image recognition processing and then, predetermined processing is performed using the reference chip. For example, during the marking or the picking up, a wafer coordinate system (X, Y, θ) and a stage coordinate system (X, Y, θ) on an apparatus side on which the wafer is mounted are adjusted using coordinates of the reference chip and coordinates of several other appropriate chips on the wafer. Then, each chip is subjected to processing such as marking or picking-up based on a corresponding relation between each chip coordinate and the stage coordinate.

Herein, a chip pattern is formed through an exposure step of transferring a pattern of a reticle onto a wafer using a stepper. On the reticle, patterns for plural chips are normally formed, so that plural chip patterns are simultaneously transferred onto the wafer by one exposure shot. Therefore, when similarly repeating the exposure shot onto different regions on the wafer, a number of predetermined chip patterns such as several hundred or several thousand are formed on the wafer.

In the case of thus forming plural chips on one wafer finally, a reference chip must be particularly accurately determined to prevent a non-defective chip from being marked or to prevent a defective chip from being accidentally selected during the picking up of non-defective chips.

Conventionally, there is proposed a method for previously forming a reference chip on a wafer (see, Japanese Unexamined Patent Application Publication No. 2003-7604). In this proposal, exposure is performed as follows. During the exposure, the whole pattern formed on a reticle is exposed onto some regions on a wafer, and an edge of the pattern formed on the reticle is partially shielded to allow only the remainder of the pattern to be exposed onto the other regions. In a chip containing a shielded part, a pattern formed on the chip is imperfect and therefore, poor electrical characteristics are shown in the probe inspection. Using the fact, a defective chip is intentionally formed on an appropriate position and used as a reference chip.

However, when specifying the reference chip by the image recognition processing, the following problems occur.

When a characteristic part on a wafer, for example, an intersection point of dicing lines is present only in one place within one image, an image recognition processor discriminates such a part and automatically specifies a reference chip based on the position of the part. On the contrary, when a number of chips such as several thousand are formed on one wafer, a number of chips having the same pattern are arranged in a matrix within one image of the image recognition processor used in specifying the reference chip. As a result, the image recognition processor becomes unable to automatically and accurately specify a reference chip from chips within the image. Therefore, when the reference chip is unable to be specified accurately, there may eventually arise the problems that a non-defective chip is marked or a defective chip is accidentally selected during the picking up of non-defective chips, as described above.

The reference chip may also be visually specified; however, in the case of forming a number of chips such as about several thousand or ten thousand on one wafer, much time and energy must be spent for specifying the reference chip using a microscope. As a result, productivity in semiconductor devices is remarkably reduced. Accordingly, it is desired that the reference chip can be automatically specified by the image recognition processing.

Further, in the conventionally proposed method for partially shielding an edge of the pattern formed on a reticle and exposing only the remainder of the pattern to intentionally form a chip having poor electrical characteristics, an imperfect pattern is formed within the chip. Therefore, there is increased the possibility that in a pattern with a part broken at some midpoint, tapering off occurs in the part to cause so-called pattern missing where the pattern with such a part is stripped and scattered in a subsequent step. Further, the chip formed by the above-described method may have no difference from other chips in appearance. In this case, when specifying the reference chip by the image recognition processing, the same problem as in the above case may occur.

### SUMMARY OF THE INVENTION

In view of the foregoing, it is an object of the present invention to provide a semiconductor device manufacturing method capable of efficiently manufacturing a semiconductor device with higher reliability.

It is another object of the present invention to provide a wafer capable of efficiently manufacturing a semiconductor device with higher reliability.

It is still another object of the present invention to provide a manufacturing method of the wafer.

To accomplish the above object, according to the present invention, there is provided a method for manufacturing a semiconductor device. This method comprises a first exposure step of performing exposure, using a first reticle, onto exposure shot regions excluding at least one exposure shot region out of all exposure shot regions of a resist formed on a wafer surface; and a second exposure step of performing exposure, using a second reticle, onto the at least one exposure shot region.

To accomplish another object, according to the present invention, there is also provided a wafer having formed thereon plural chips. This wafer comprises a first chip; and a second chip which can be discriminated from the first chip by image recognition and which acts as a benchmark for a location of the first chip.

To accomplish still another object, according to the present invention, there is also provided a method for manufacturing a wafer having formed thereon plural chips, comprising a first exposure step of performing exposure, using a first reticle, onto exposure shot regions excluding at least one exposure shot region out of all exposure shot regions of a resist formed on a wafer surface; and a second exposure step of performing exposure, using a second reticle, onto the at least one exposure shot region.

The above and other objects, features and advantages of the present invention will become apparent from the following description when taken in conjunction with the accompanying drawings which illustrate preferred embodiments of the present invention by way of example.

### BRIEF DESCRIPTION OF THE DRAWINGS

FIG. 1 shows a wafer formation flow according to a first embodiment.

FIG. 2 is a schematic sectional view showing an essential part (part one) of an uppermost layer wiring formation step.

FIG. 3 is a schematic sectional view showing an essential part (part two) of an uppermost layer wiring formation step.

FIG. 4 is a schematic sectional view showing an essential part (part three) of an uppermost layer wiring formation step.

FIG. 5 illustrates a forming method of an uppermost layer wiring formation resist pattern.

FIG. 6 is a schematic sectional view showing an essential part of a passivation film formation step.

FIG. 7 is a schematic sectional view showing an essential part of an exposure step of a pad formation resist pattern.

FIG. 8 illustrates a forming method of a pad formation exposure region.

FIG. 9 is a schematic sectional view showing an essential part of an exposure step of an L/S pattern.

FIG. 10 is a schematic sectional view showing an essential part of a product chip.

FIG. 11 is a schematic plan view showing an essential part of a product chip.

FIG. 12 is a schematic sectional view showing an essential part of a reference chip.

FIG. 13 is a schematic plan view showing an essential part of a reference chip.

FIG. 14 illustrates a line pattern of a reticle.

FIG. 15 shows a configuration example of a reticle used for formation of a reference chip.

FIG. 16 shows a wafer formation flow according to a second embodiment.

FIG. 17 shows a wafer formation flow according to a third embodiment.

### DESCRIPTION OF THE PREFERRED EMBODIMENTS

Preferred embodiments of the present invention will be described in detail below with reference to the accompanying drawings, wherein like reference numerals refer to like elements throughout.

A first embodiment will be described first.

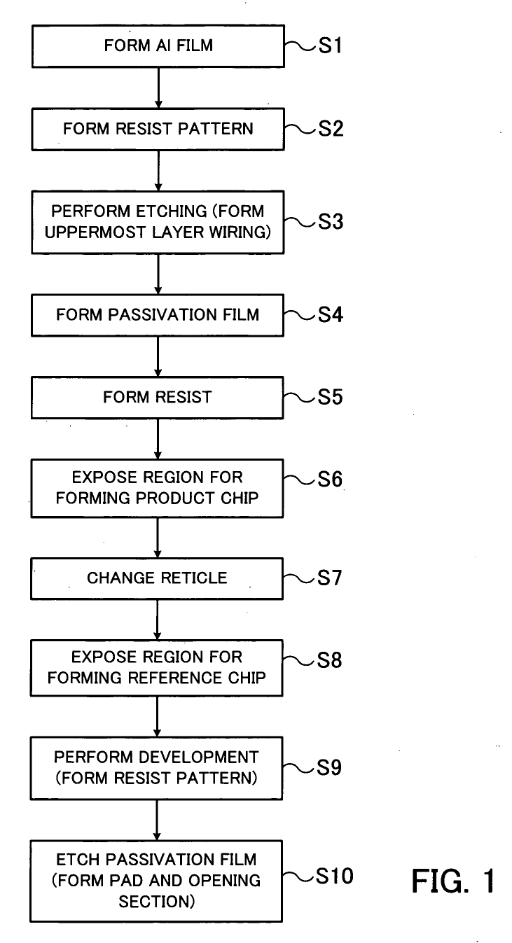

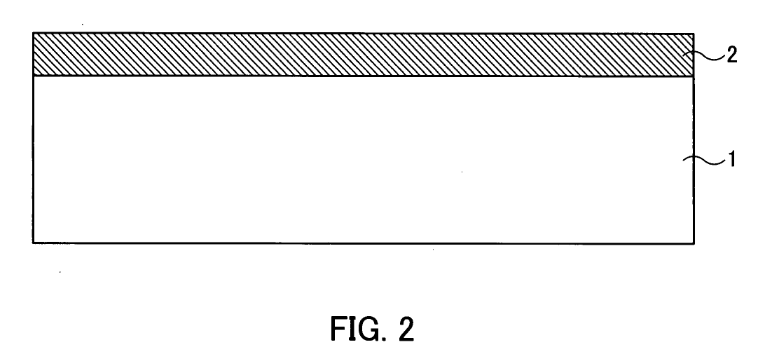

FIG. 1 shows a wafer formation flow according to a first embodiment. Herein, the wafer formation flow in forming a semiconductor device will be described. Particularly, the wafer formation flow after formation of an uppermost layer wiring after forming a predetermined transistor structure and multilayer wiring structure will be described. FIGS. 2 to 4 are schematic sectional views showing essential parts of an uppermost layer wiring formation step.

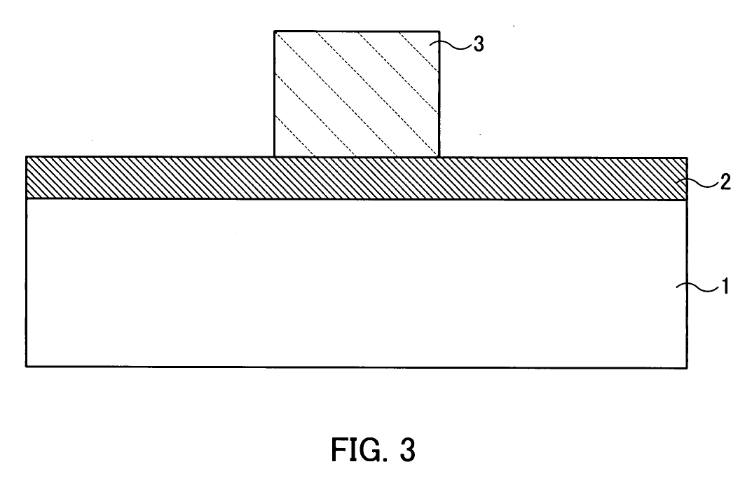

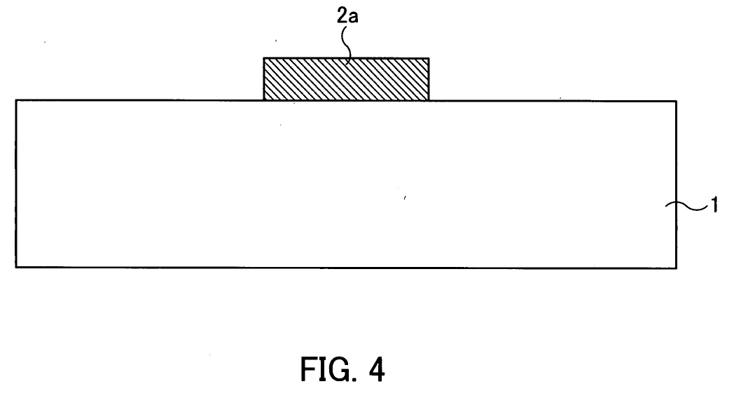

In the first embodiment, after forming a predetermined transistor structure and multilayer wiring structure by the ordinary method, an uppermost layer wiring is formed as follows. As shown in FIG. 2, an aluminum (Al) film 2 as a wiring layer with a predetermined film thickness is first formed on the whole surface of a substrate 1 having formed thereon such a transistor structure and multilayer wiring structure (both structures are not shown) (step S1). Subsequently, as shown in FIG. 3, a resist 3 is formed on the whole surface and then, predetermined exposure and development are performed onto the resist 3 to form a resist pattern for uppermost layer wiring formation (step S2). After the formation of the resist pattern, the Al film 2 is etched using the pattern as a mask. Thereafter, the resist 3 is removed to form an uppermost layer wiring 2a of Al in a predetermined region on the substrate 1, as shown in FIG. 4 (step S3).

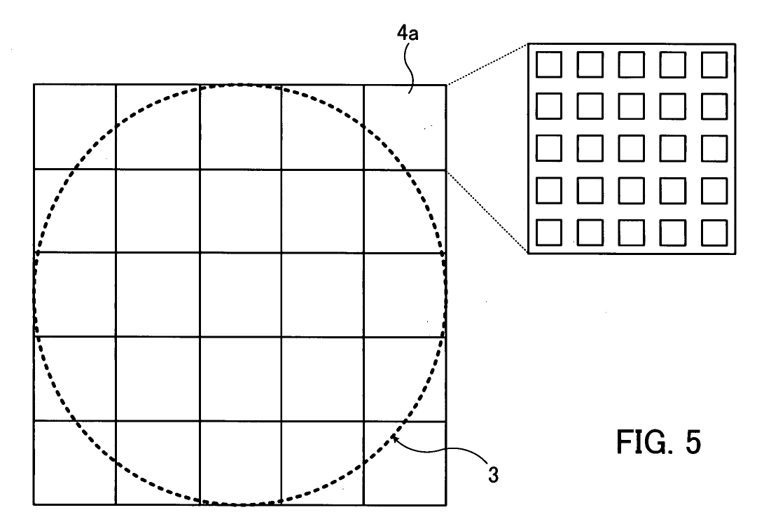

Herein, FIG. 5 illustrates a forming method of the resist pattern for uppermost layer wiring formation.

When performing the exposure onto the resist 3 in step S2 for forming the uppermost layer wiring 2a, there is used one reticle (one type) on which patterns with the same shape as that of the uppermost layer wiring 2a to be formed are formed for plural chips. Using such a reticle, an exposure shot is sequentially repeated onto each previously set exposure shot region 4a (totally, 25 places), as shown in FIG. 5. Finally, exposure using the reticle is performed onto the whole region of the resist 3. Subsequently, this resist 3 after the exposure is developed, whereby resist patterns for plural chips are formed on the resist 3 of the respective exposure shot regions 4a. Thereafter, the Al film 2 is etched using the resist pattern as a mask. Thus, the uppermost layer wiring 2a is formed on each chip.

In the first embodiment, after thus forming the uppermost layer wirings 2a for all chips to be formed on the wafer, a product chip and a reference chip are manufactured separately. A method therefor will be described in sequence below with reference to FIG. 1 and FIGS. 6 to 13.

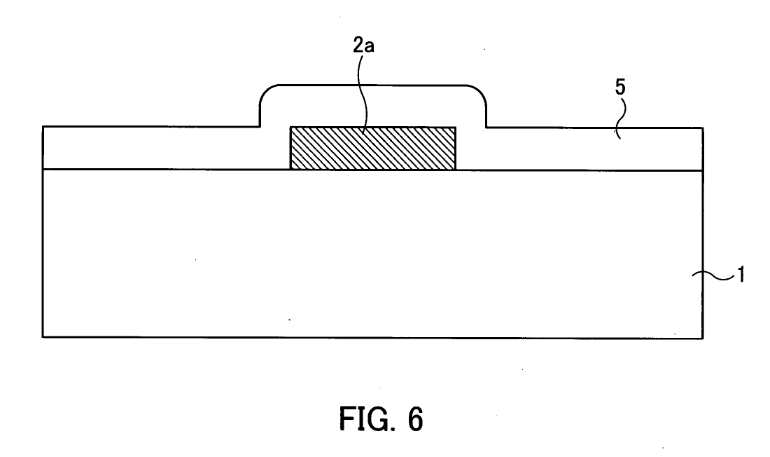

FIG. 6 is a schematic sectional view showing an essential part of a passivation film formation step.

After the formation of the uppermost layer wiring 2a, a passivation film 5 with a predetermined film thickness is first formed on the whole surface (step S4), as shown in FIG. 6. The passivation film 5 is formed of a single layer or a laminated structure using an insulating film such as a silicon oxide (SiO₂) film or a silicon nitride (SiN) film. After the formation of the passivation film 5, a window opening process is performed on a predetermined region of the passivation film 5 in order to form a bonding pad of a product chip.

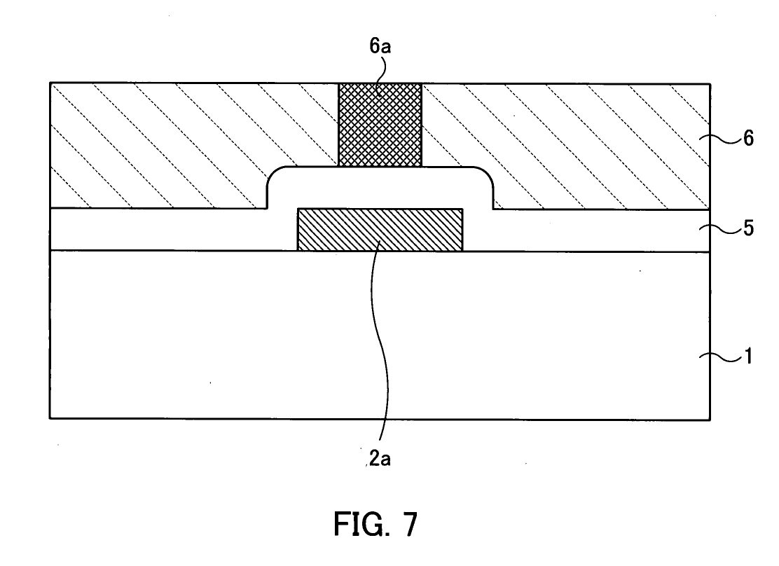

FIG. 7 is a schematic sectional view showing an essential part of an exposure step of a pad formation resist pattern.

In window opening process on the passivation film 5, a resist 6 is first formed on the whole surface, as shown in FIG. 7 (step S5). Then, using a reticle on which patterns with the same shape as that of the pad of a product chip are formed for plural chips, a predetermined exposure is performed onto the resist 6 on a region for forming the product chip (step S6). Thus, an exposure region 6a is formed.

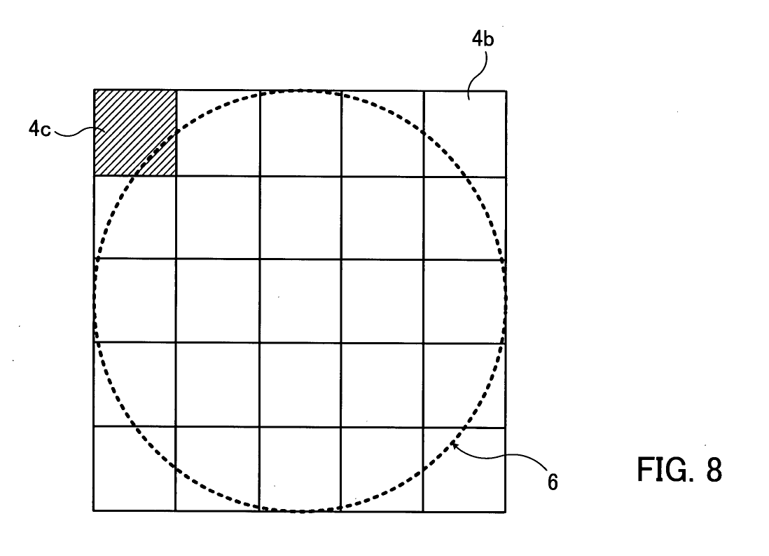

Herein, FIG. 8 illustrates a forming method of a pad formation exposure region.

The exposure onto the resist 6 in step S6 is performed as follows. Using the above-described predetermined reticle, the exposure is sequentially repeated onto each previously set exposure shot region 4b, as shown in FIG. 8; however, no exposure is performed onto any one of exposure shot regions, that is, an exposure shot region 4c. As a result, the exposure region 6a for pad formation as shown in FIG. 7 is formed only in the resist 6 on the exposure shot region 4b (totally, 24 places).

After thus forming the exposure region 6a, the reticle previously used for formation of the exposure region 6a is changed to a reticle on which patterns with a shape different from that of a pad of the product chip are formed for plural chips (step S7). Then, using the changed reticle, exposure is performed onto the remaining exposure shot region 4c shown in FIG. 8 (step S8). Thus, an exposure region for forming a pattern with a shape different from that of a pad of the product chip, that is, a pattern of the reference chip is formed in the resist 6 of the exposure shot region 4c.

The reticle used in step S8 may be a reticle having formed thereon a pattern with a shape different from that of a pad of the product chip, for example, a line and space (L/S) pattern comprising plural line patterns disposed in line. A detailed configuration of a reticle which can be used herein will be described later.

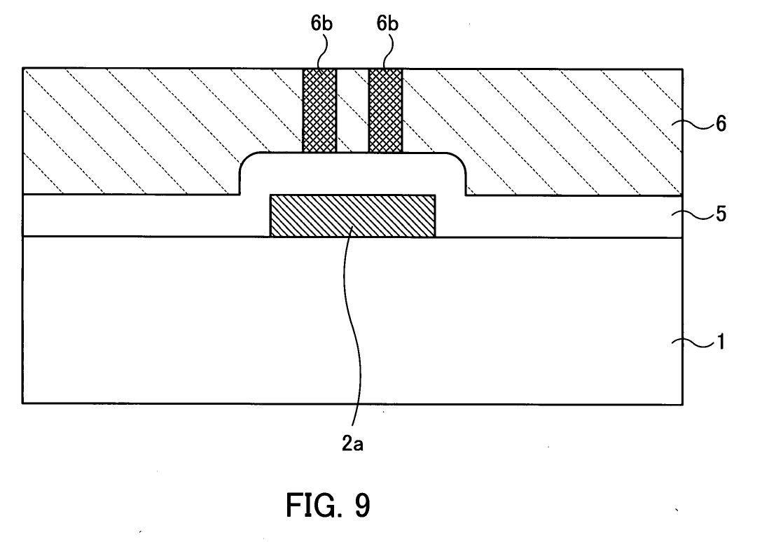

FIG. 9 is a schematic sectional view showing an essential part of an exposure step of an L/S pattern.

When the exposure onto the exposure shot region 4c shown in FIG. 8 is performed using, for example, a reticle having formed thereon an L/S pattern comprising two line patterns disposed in line, an exposure region 6b with a shape corresponding to that of the L/S pattern is formed in the resist 6 on the exposure shot region 4c, as shown in FIG. 9.

After thus exposing the respective exposure shot regions 4b and 4c of the resist 6 using the predetermined reticle to respectively form the exposure region 6a with a shape corresponding to that of a pad of the product chip and the exposure region 6b with a shape corresponding to that of an L/S pattern of the reference chip, development of the whole resist 6 is performed (step S9). Thus, both of the exposure regions 6a and 6b are removed, whereby a resist pattern for forming a pad of the product chip and a resist pattern for forming an L/S pattern of the reference chip are simultaneously formed on the resist 6.

Further, using as a mask the resist 6 having formed thereon such resist patterns, the passivation film 5 is etched to form a pad on the product chip as well as to form a slit-like opening section in the reference chip (step S10).

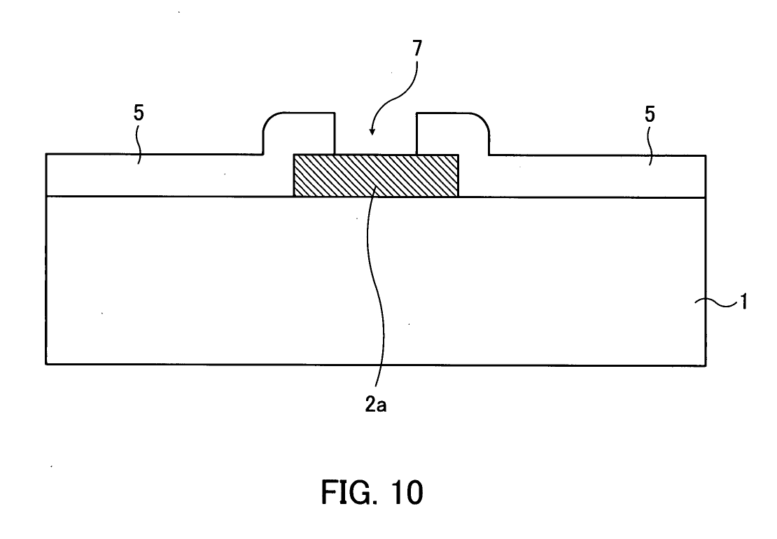

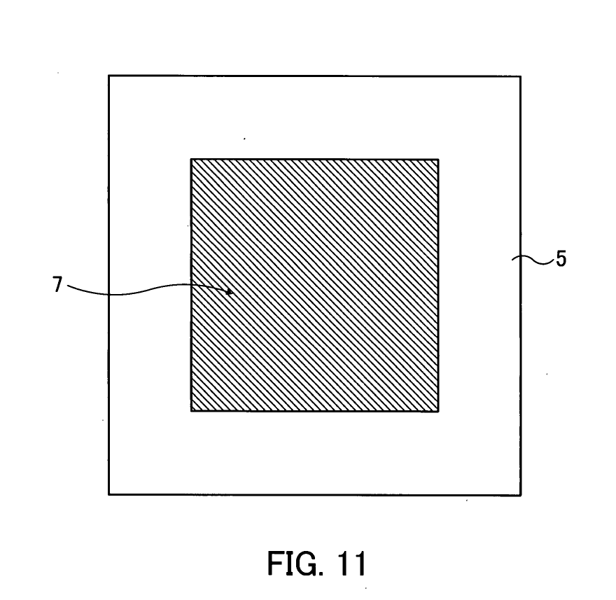

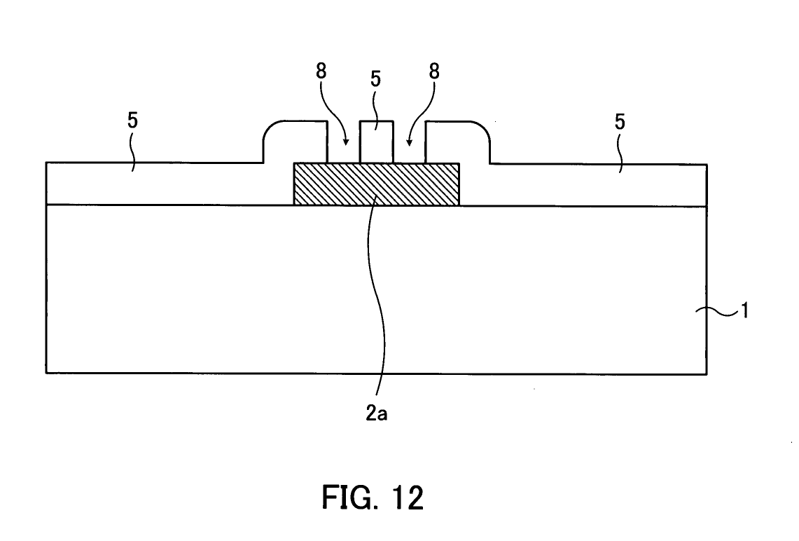

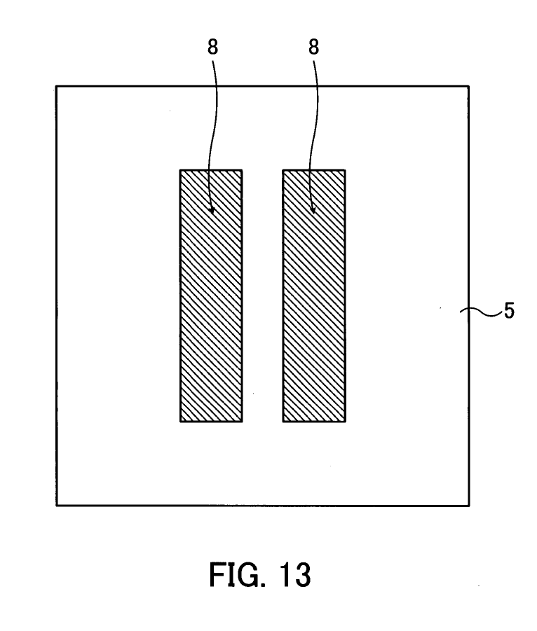

FIG. 10 is a schematic sectional view showing an essential part of the product chip and FIG. 11 is a schematic plan view showing an essential part of the product chip. Further, FIG. 12 is a schematic sectional view showing an essential part of the reference chip and FIG. 13 is a schematic plan view showing an essential part of the reference chip.

In the product chip, the passivation film 5 is etched to expose a part of Al of the uppermost layer wiring 2a, whereby a pad 7 is formed as shown in FIGS. 10 and 11. This pad 7 is finally subjected to wire bonding. On the other hand, in the reference chip, the passivation film 5 is etched to expose Al, whereby two slit-like opening sections 8 are formed as shown in FIGS. 12 and 13.

When forming a wafer according to the above-described flow, there can be obtained a wafer with most regions in which product chips are formed as well as with some regions in which reference chips are formed. In such a wafer, a product chip having formed thereon the pad 7 and a reference chip having formed therein two slit-like opening sections 8 are different from each other in a planar shape or area of Al exposed on the surface. Therefore, even if using a conventional image recognition processor, discrimination between the product chip and the reference chip can be sufficiently performed due to a difference in the planar shape or surface contrasting of the exposed Al.

Accordingly, the reference chip can be automatically specified accurately using the image recognition processor. Thus, positioning of the wafer is precisely performed so that a position of each chip can be accurately grasped. Therefore, it becomes possible to prevent a non-defective chip from being marked in an inspection step or to prevent a defective chip from being accidentally selected during the picking up of non-defective chips in an assembling step. As a result, a product chip with higher reliability can be efficiently formed as well as various semiconductor devices using such chips can be efficiently formed.

According to the above-described wafer formation flow, a reticle for forming the reference chip may be prepared separately from a reticle for forming the product chip to allow the predetermined exposure shot regions to be exposed using the respective reticles. Therefore, the discriminable product chip and reference chip can be formed at low cost without newly introducing facilities or altering large facilities. As a result, a product chip with higher reliability and a semiconductor device using the same can be formed at low cost.

In the above-described example, the passivation film 5 is formed after the formation of the uppermost layer wiring 2a (steps S3 and S4). Further, before the formation of the passivation film 5, an antireflection film may be formed at least on the uppermost layer wiring 2a using titanium nitride (TiN). During the subsequent etching in forming the pad 7 and the two slit-like opening sections 8 (step S10), the antireflection film is removed from regions of the pad 7 and the opening sections 8; however, the antireflection film remains on the uppermost layer wiring 2a other than those regions. Therefore, in the image recognition processing, an influence of reflection from the uppermost layer wiring 2a is suppressed so that a difference in the planar shape or surface contrasting of the pad 7 and the opening sections 8 can be detected.

Herein, a configuration of the reticle used for formation of the above-described reference chip will be described in detail.

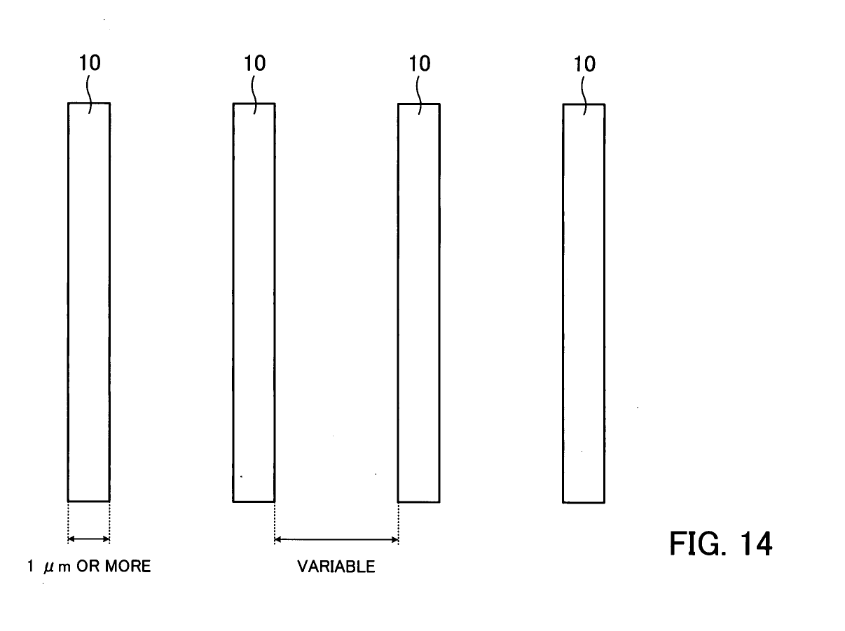

FIG. 14 illustrates a line pattern of a reticle.

In the description, the L/S pattern comprising two line patterns is formed for a reticle used for the formation of the reference chip; however, the number of the line patterns is not of course limited to two line patterns.

When forming the L/S pattern on a reticle, plural line patterns 10 may be vertically spaced out in parallel within one chip region, as shown in FIG. 14. Of course, these line patterns 10 may be horizontally spaced out in parallel within one chip region. Alternatively, the line patterns 10 may be disposed in a matrix in a plane. Outside of disposing the line patterns vertically, horizontally or in a matrix, the patterns 10 may be disposed obliquely. In view of easiness of the pattern formation, it is desired that the line patterns 10 are disposed vertically, horizontally or in a matrix.

When forming a chip with a size of 1 mm², a width of the line pattern 10 is set to 1 μm or more, preferably about 5 μm, depending on a reduction ratio during exposure. A space between the respective line patterns 10 can be set to various values as described later. By setting the width of the line pattern 10 in such a range, discrimination between the reference chip having transferred thereon this line pattern 10 and the product chip having transferred thereon the pad pattern is surely performed by the image recognition processing.

Further, when forming the line pattern 10, it is desired that an occupied area (or an occupied area of a shielding section) of the line pattern 10 within the reticle is the same as that (or an occupied area of the shielding section) of the pad pattern within the reticle having formed thereon the pattern of the pad 7 of the product chip, or a difference between the occupied areas is set in a range of ±10%. By doing so, also when using two types of reticles having formed thereon different patterns, an influence of wafer in-plane distribution or film stress due to etching at the time of transferring patterns can be suppressed. Particularly, a high yield rate of the non-defective product chip near the reference chip can be maintained. The occupied area of the line pattern 10 within the reticle can be adjusted by the width or number of the line patterns 10 or the space between the line patterns 10.

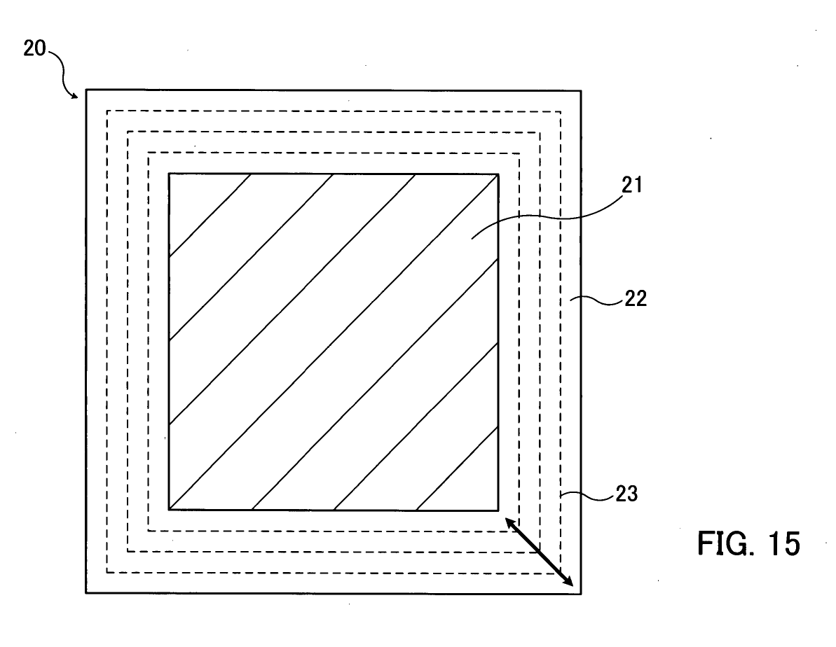

FIG. 15 shows a configuration example of a reticle used for formation of the reference chip.

A reticle 20 shown in FIG. 15 has a central region (reference chip pattern region) 21 having formed therein patterns such as L/S patterns for plural chips. Further, the reference chip pattern region 21 is surrounded by an outer peripheral region 22 having formed therein no pattern.

In this reticle 20, the sizes of the reference chip pattern region 21 and the external region 22 are set so as to correspond to various exposure shot sizes. That is, in the reticle 20, a blind size 23 of a stepper can be arbitrarily changed in a range of the external region 22 as shown in FIG. 15 by a broken line. Further, in the reticle 20, also when the blind size 23 is changed, the reference chip pattern is surely transferred to the wafer side. Therefore, a missing pattern is prevented from being transferred so that a problem such as a pattern missing can be avoided as well as the reticle 20 can be applied to the formation of chips with various shapes.

As described above, when forming a wafer having a product chip and a reference chip according to the above-described flow, the reference chip can be accurately specified within the wafer. Further, a product chip having higher reliability and a semiconductor device using the chip can be formed from such a wafer.

In the above-described description, the L/S pattern is used as the reference chip pattern. Further, when discrimination between the reference chip pattern and the pad 7 of the product chip can be performed in terms of the image recognition processing, reference chip patterns with other shapes may be used. Further, in the description, a case of separately forming the reference chip pattern in each chip region is described by way of example. The reference chip pattern can also be formed astride the chip regions for plural chips. Further, a reticle on which no specified pattern is formed so as to strip off the whole wiring on the uppermost layer may be used for forming the reference chip.

Further, in the above description, the reference chip is formed on the edge of the wafer. Further, the reference chip may be formed not only in such an edge region but also in any region on the wafer. However, since the edge of the wafer is generally a region with the high possibility of occurrence of defective chips as compared with the central part of the wafer, the reference chip not used as the product chip is preferably formed on the wafer edge in order to suppress a decrease in yield of the product chips.

In the description, a case of forming the reference chip only in one exposure shot region is described by way of example. Further, the reference chip may be formed in the plural exposure shot regions. However, when making an attempt to obtain many product chips from one wafer, the number of the exposure shot regions in which the reference chip is formed is preferably reduced as small as possible. In general, one region having formed therein such a reference chip suffices.

Further, the above-described wafer formation flow can be applied to a case of forming a chip with a size within the range of the image recognition processor used. Particularly, the flow is suitable for a case of forming a small chip such as a chip with a size of 1 mm² or less. This is because when forming such a small chip, there arises easily a problem that in the above-described image recognition processing, the reference chip cannot be accurately specified due to many chips within one image.

Next, a second embodiment will be described.

In the first embodiment, the product chip and the reference chip are separately manufactured after forming the uppermost layer wiring on the wafer. To the contrary, in the second embodiment, the product chip and the reference chip are separately manufactured in the formation of the uppermost layer wiring on the wafer. Also in the second embodiment, the wafer formation flow after formation of the uppermost layer wiring after forming a predetermined transistor structure and multilayer wiring structure will be described in the same manner as in the first embodiment.

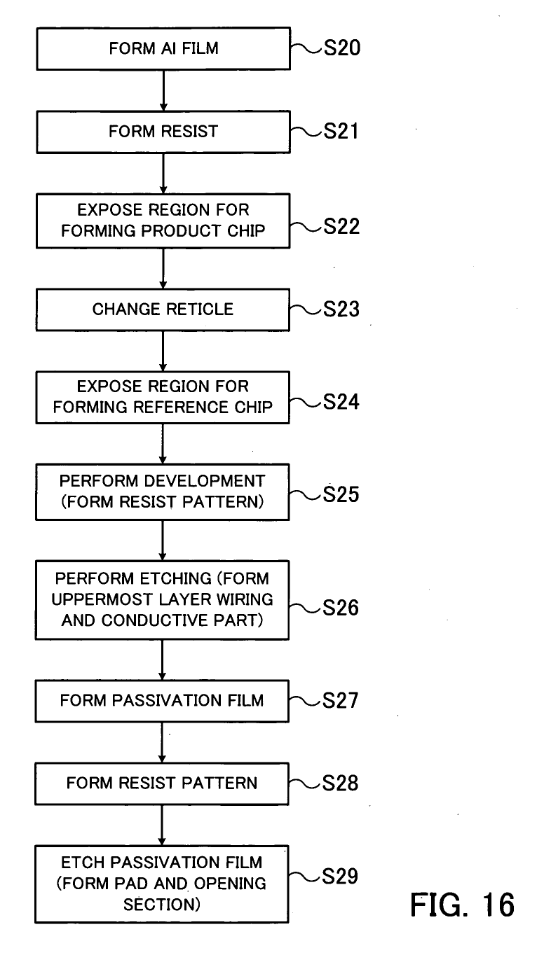

FIG. 16 shows the wafer formation flow according to the second embodiment.

In the same manner as in the first embodiment, an Al film as a wiring layer is first formed on a substrate having formed thereon a predetermined transistor structure and multilayer wiring structure (step S20) and then, a resist is formed on the whole surface (step S21).

Further, using a reticle having formed thereon the uppermost layer wiring formation pattern to be formed on the product chip, exposure is sequentially repeated onto the exposure shot regions (see, the exposure shot region 4b in FIG. 8) for forming the product chip (step S22). Thereafter, the reticle is changed to a reticle having formed thereon a pattern with a shape different from that of the uppermost layer wiring formation pattern, for example, a reticle having formed thereon the above-described L/S pattern (step S23). Using the changed reticle, exposure is performed onto the remaining exposure shot region (see, the exposure shot region 4c in FIG. 8) for forming the reference chip (step S24). Thus, an exposure region for forming the uppermost layer wiring of the product chip and an exposure region for forming the wiring pattern (conductive part) of the reference chip are formed on the resist.

After the formation of the respective exposure regions, development of the whole resist is performed to simultaneously form on the resist a resist pattern for forming the uppermost layer wiring of the product chip and a resist pattern for forming the conductive part of the reference chip (step S25). Using the resist patterns as a mask, the Al film is etched to simultaneously form the uppermost layer wiring of the product chip as well as the conductive part of the reference chip (step S26).

Thereafter, a passivation film is formed on the whole surface (step S27) and further, a resist is formed on the whole surface. Then, using a reticle having formed thereon a pad pattern of the product chip, exposure is sequentially repeated onto all the exposure shot regions (see, the exposure shot region 4a in FIG. 5). After the exposure, development of the whole resist is performed to form a resist pattern (step S28). Further, using the obtained resist pattern as a mask, the passivation film is etched to form a pad of the product chip and an opening section of the reference chip (step S29). A shape of the opening section of the reference chip formed herein is the same as that of the pad of the product chip; however, the opening section is not used as the pad.

Also when forming a wafer having the product chip and the reference chip according to such a flow, the product chip and the reference chip are different from each other in a patterning shape of the wiring layer. Therefore, when using the image recognition processor, discrimination between the product chip and the reference chip can be sufficiently performed due to a difference in the wiring shape or the surface contrasting. As a result, the reference chip can be accurately specified within the wafer. Further, a product chip with higher reliability can be formed from such a wafer as well as a semiconductor device using such a chip can be formed.

In the second embodiment, in the same manner as in the first embodiment, a reticle as shown in FIGS. 14 and 15 can be used for the reticle used for wiring formation of the reference chip. In addition, a pattern other than the L/S pattern can also be used for the reticle. Further, in the same manner as in the first embodiment, the reference chip may be formed in any region on the wafer, or alternatively, the chip may be formed in plural exposure shot regions. Further, the wafer formation flow described herein can be applied to a case of forming a chip with a size within the range of the image recognition processor used.

Next, a third embodiment will be described.

In the third embodiment, after forming a pad of the uppermost layer through a normal procedure, a photosensitive resist polyimide (PI) film as a buffer film between a chip and a mold resin is finally formed. Then, the product chip and the reference chip are manufactured separately during the patterning of the PI film. Also in the third embodiment, the wafer formation flow after formation of an uppermost layer wiring after forming a predetermined transistor structure and multilayer wiring structure will be described in the same manner as in the first embodiment.

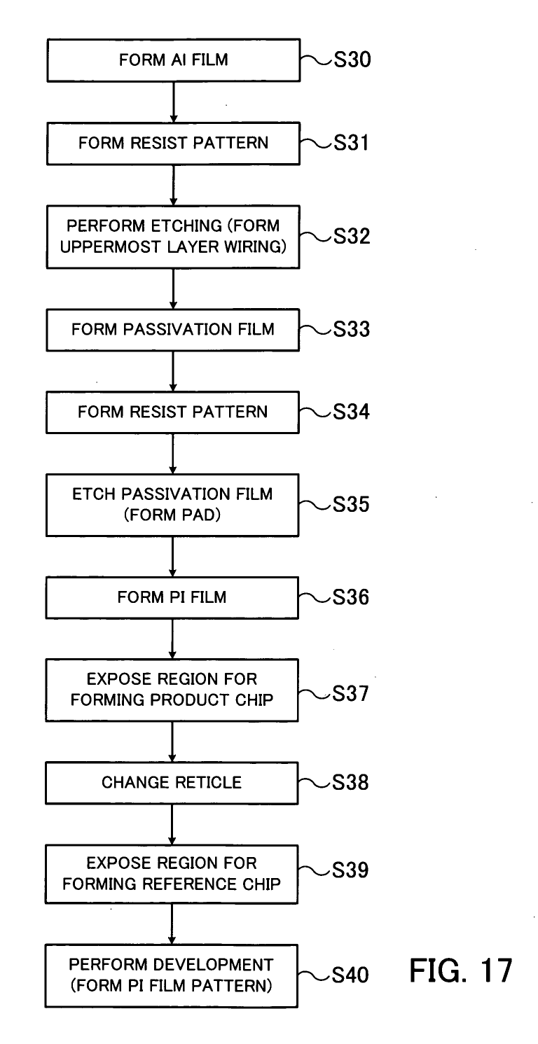

FIG. 17 shows the wafer formation flow according to the third embodiment.

First, an Al film is formed on a substrate having formed thereon a predetermined transistor structure and multilayer wiring structure (step S30). Next, a resist is formed on the whole surface. Further, using a reticle having formed thereon the uppermost layer wiring formation pattern to be formed on the product chip, exposure is performed onto all the exposure shot regions (see, the exposure shot region 4a in FIG. 5). After the exposure, development of the whole resist is performed to form on the resist a resist pattern for forming the uppermost layer wiring of the product chip (step S31). Further, using the resist pattern as a mask, etching of the Al film is performed to form the uppermost layer wiring of the product chip (step S32).

Thereafter, a passivation film is formed on the whole surface (step S33) and further, a resist is formed on the whole surface. Then, using a reticle having formed thereon a pattern of a pad to be formed on the product chip, exposure is performed onto all the exposure shot regions (see, the exposure shot region 4a in FIG. 5). After the exposure, development of the whole resist is performed to form a resist pattern (step S34).

Further, using the obtained resist pattern as a mask, etching of the passivation film is performed to form a pad of the product chip (step S35).

Herein, after the formation of the pad, a PI film is first formed on the whole surface (step S36). Then, using a reticle having formed thereon a PI film pattern to be formed on the product chip, exposure is performed onto the PI film in the exposure shot region (see, the exposure shot region 4b in FIG. 8) for forming the product chip (step S37). Thereafter, the reticle is changed to a reticle having formed thereon a PI film pattern different from that of the product chip, for example, a reticle having formed thereon the above-described L/S pattern (step S38). Using the changed reticle, exposure is performed onto the PI film in the remaining exposure shot region (see, the exposure shot region 4c in FIG. 8) for forming the reference chip (step S39). Finally, development of the whole resist is performed to form a predetermined PI film pattern on each of the product chip and the reference chip (step S40).

Also when forming a wafer having the product chip and the reference chip according to such a flow, the product chip and the reference chip are different from each other in a patterning shape of the PI film. Therefore, when using the image recognition processor, discrimination between the product chip and the reference chip can be sufficiently performed due to a difference in the shape or surface contrasting of the PI film. As a result, the reference chip can be accurately specified within the wafer. Further, a product chip with higher reliability can be formed from such a wafer as well as a semiconductor device using such a chip can be formed.

Also in the third embodiment, in the same manner as in the first embodiment, a reticle as shown in FIGS. 14 and 15 can be used for the reticle used for PI film formation of the reference chip. In addition, a pattern other than the L/S pattern can also be used for the reticle. Further, in the same manner as in the first embodiment, the reference chip may be formed in any region on the wafer, or alternatively, the chip may be formed in plural exposure shot regions. Further, the wafer formation flow described herein can be applied to a case of forming a chip with a size within the range of the image recognition processor used.

In the present invention, exposure using a first reticle is performed onto exposure shot regions excluding at least one exposure shot region out of all exposure shot regions of a resist formed on a wafer surface, and exposure using a second reticle is performed onto the at least one exposure shot region. As a result, discrimination between the chips formed by performing exposure using the first and second reticles can be performed by the image recognition processing so that positions of the respective chips can be accurately grasped. Accordingly, marking on non-defective chips and picking up of defective chips can be prevented from occurring so that a chip with higher reliability can be efficiently formed. Further, a semiconductor device with higher reliability can be formed using such a chip.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A method for manufacturing a semiconductor device, comprising:
a first exposure step of performing exposure, using a first reticle, onto exposure shot regions excluding at least one exposure shot region out of all exposure shot regions of a resist formed on a wafer surface; and
a second exposure step of performing exposure, using a second reticle, onto the at least one exposure shot region.

2. The method according to claim 1, which further comprises, before the first exposure step, the steps of:
forming a wiring;
forming an insulating film which covers the wiring; and
forming the resist on the insulating film, wherein:
in the first exposure step, there is used the first reticle having formed thereon a first pattern for opening the insulating film to form a pad on a part of the wiring; and
in the second exposure step, there is used the second reticle having formed thereon a second pattern different from the first pattern.

3. The method according to claim 2, which further comprises, after the second exposure step, the steps of:
developing the resist having exposed thereon the first pattern and the second pattern to form a resist pattern; and
etching the insulating film using the resist pattern.

4. The method according to claim 1, which further comprises, before the first exposure step, the steps of:
forming a wiring layer; and
forming the resist on the wiring layer, wherein:
in the first exposure step, there is used the first reticle having formed thereon a first pattern for patterning the wiring layer to form a wiring; and
in the second exposure step, there is used the second reticle having formed thereon a second pattern different from the first pattern.

5. The method according to claim 4, which further comprises, after the second exposure step, the steps of:
developing the resist having exposed thereon the first pattern and the second pattern to form a resist pattern;
etching the wiring layer using the resist pattern to form the wiring;
forming an insulating film which covers the wiring; and
opening by etching the insulating film to form a pad on a part of the wiring.

6. The method according to claim 1, which further comprises, before the first exposure step, the steps of:
forming a wiring;
forming an insulating film which covers the wiring;
opening by etching the insulating film to form a pad on a part of the wiring; and
forming, on the whole surface, the resist as a buffer film, wherein:
in the first exposure step, there is used the first reticle having formed thereon a first pattern; and
in the second exposure step, there is used the second reticle having formed thereon a second pattern different from the first pattern.

7. The method according to claim 6, wherein after the second exposure step, the resist having exposed thereon the first pattern and the second pattern is developed to form a pattern of the buffer film.

8. The method according to claim 1, wherein an L/S pattern is formed on the second reticle.

9. The method according to claim 1, wherein the first reticle and the second reticle have a difference of ±10% or less in an occupied area of a shielding part.

10. The method according to claim 1, wherein the second reticle has, in an outer periphery of a central part having formed thereon a pattern, an outer peripheral part having formed thereon no pattern so that a blind size can be changed within the outer peripheral part.

11. A wafer having formed thereon plural chips, comprising:
a first chip; and
a second chip which can be discriminated from the first chip by image recognition and which acts as a benchmark for a location of the first chip.

12. The wafer according to claim 11, wherein the second chip has an opening section with a shape different from that of a pad formed on the first chip.

13. The wafer according to claim 11, wherein the second chip has another wiring with a shape different from that of a wiring formed on the first chip.

14. The wafer according to claim 11, wherein the second chip has another buffer film with a shape different from that of a buffer film formed on the first chip.

15. The wafer according to claim 11, wherein the second chip is formed for at least one exposure shot region out of all exposure shot regions.

16. A method for manufacturing a wafer having formed thereon plural chips, comprising:
a first exposure step of performing exposure, using a first reticle, onto exposure shot regions excluding at least one exposure shot region out of all exposure shot regions of a resist formed on a wafer surface; and
a second exposure step of performing exposure, using a second reticle, onto the at least one exposure shot region.

17. The method according to claim 16, which further comprises, before the first exposure step, the steps of:
forming a wiring;
forming an insulating film which covers the wiring; and
forming the resist on the insulating film, wherein:
in the first exposure step, there is used the first reticle having formed thereon a first pattern for opening the insulating film to form a pad on a part of the wiring; and
in the second exposure step, there is used the second reticle having formed thereon a second pattern different from the first pattern.

18. The method according to claim 16, which further comprises, before the first exposure step, the steps of:
forming a wiring layer; and
forming the resist on the wiring layer, wherein:
in the first exposure step, there is used the first reticle having formed thereon a first pattern for patterning the wiring layer to form a wiring; and
in the second exposure step, there is used the second reticle having formed thereon a second pattern different from the first pattern.

19. The method according to claim 16, which further comprises, before the first exposure step, the steps of:
forming a wiring;
forming an insulating film which covers the wiring;
opening by etching the insulating film to form a pad on a part of the wiring; and
forming, on the whole surface, the resist as a buffer film, wherein:
in the first exposure step, there is used the first reticle having formed thereon a first pattern; and
in the second exposure step, there is used the second reticle having formed thereon a second pattern different from the first pattern.
